(19) United States
(12) Patent Application Publication
(10) Pub. No.: US 2021/0162470 A1
(43) Pub. Date: Jun. 3, 2021

(54) SELF-CLEANING WIRE BONDING MACHINE

(71) Applicant: TRIPLE WIN TECHNOLOGY(SHENZHEN) CO.LTD., Shenzhen (CN)

(72) Inventors: YAN-XIN FENG, Jincheng (CN); GAO-CAI CAO, Jincheng (CN); PENG-CHENG NIU, Jincheng (CN)

(21) Appl. No.: 16/725,753

(22) Filed: Dec. 23, 2019

(30) Foreign Application Priority Data
Nov. 29, 2019 (CN) 201911199564.1

(51) Int. Cl. B08B 9/023; H01L 23/00

(52) U.S. Cl. CPC B08B 9/023; H01L 2224/7801; H01L 24/78

(57) ABSTRACT

A self-cleaning wire bonding machine includes a spool, a cleaning tank, a drying element, a tensioner, and a nozzle. The spool includes a rotating body and a metal wire wound around the rotating body. The cleaning tank is configured to clean the metal wire after the rotating body passes the metal wire through the cleaning tank. The drying element is configured to dry the metal wire after passing through the cleaning tank. The tensioner is configured to adjust a tension of the metal wire. The nozzle is configured to heat the metal wire, and the metal wire exits out of the nozzle after being heated.

### FIELD

The subject matter herein generally relates to wire bonding machines, and more particularly to a self-cleaning wire bonding machine.

### BACKGROUND

Generally, a main function of a wire bonding machine is to bond wafers and circuit boards through metal wires (such as gold wires, copper wires and aluminum wires) under a certain temperature, pressure, and power, so as to realize transmission of electronic signals. However, the metal wires are prone to contamination due to the long-term exposure to the air, and pollutants are likely to cause the wire to become stuck in an outlet path, which may cause the wires to break.

### BRIEF DESCRIPTION OF THE DRAWINGS

Implementations of the present disclosure will now be described, by way of embodiments, with reference to the attached figures.

FIG. 1 is an assembled, schematic view of an embodiment of a self-cleaning wire bonding machine.

FIG. 2 is a schematic view of a cleaning tank of the self-cleaning wire bonding machine in FIG. 1.

FIG. 3 is an isometric view of the cleaning tank in FIG. 2.

FIG. 4 is an isometric view of a pressing rod of the cleaning tank.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

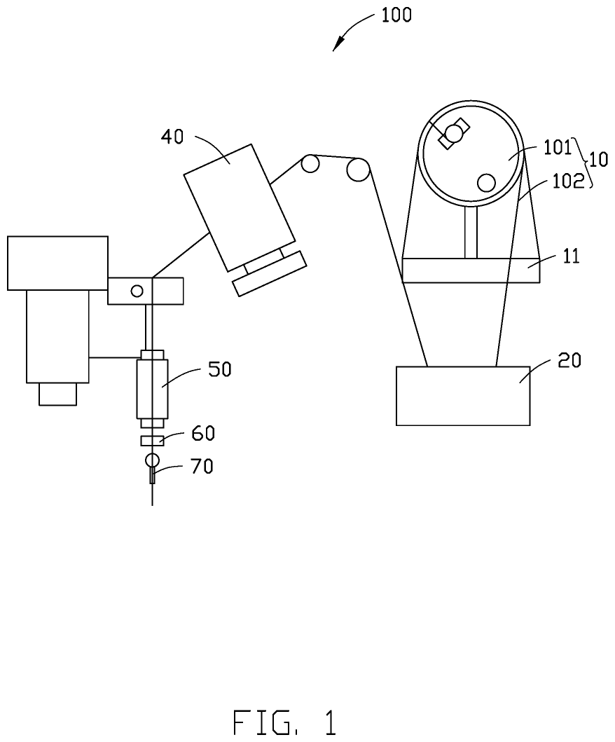

FIG. 1 shows an embodiment of a self-cleaning wire bonding machine 100 (hereinafter “the wire bonding machine 100”). The wire bonding machine 100 includes a spool 10, a cleaning tank 20, a drying element 40, a tensioner 50, a wire clamp 60, and a nozzle 70 sequentially arranged. The wire bonding machine 100 is used for soldering a product (not shown) to be processed. The product to be processed may be a circuit board.

The spool 10 includes a substantially cylindrical rotating body 101 and a metal wire 102 wound around the rotating body 101. The rotating body 101 is located on a support base 11 and rotates on the support base 11. Rotation of the rotating body 101 enables the metal wire 102 to be wound on the spool 10. The metal wire 102 may be a gold wire, a copper wire, or an aluminum wire. In one embodiment, the metal wire 102 is a gold wire.

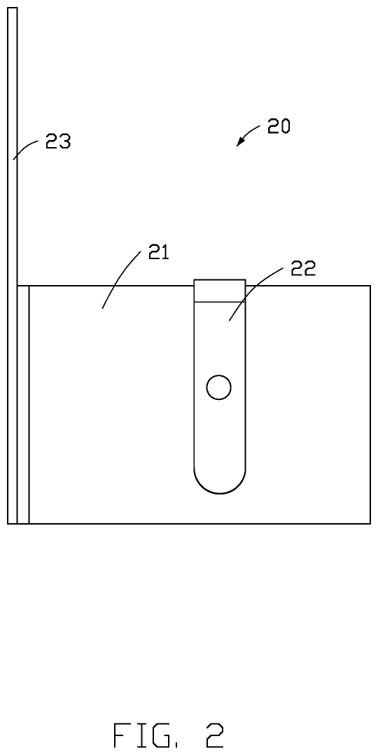

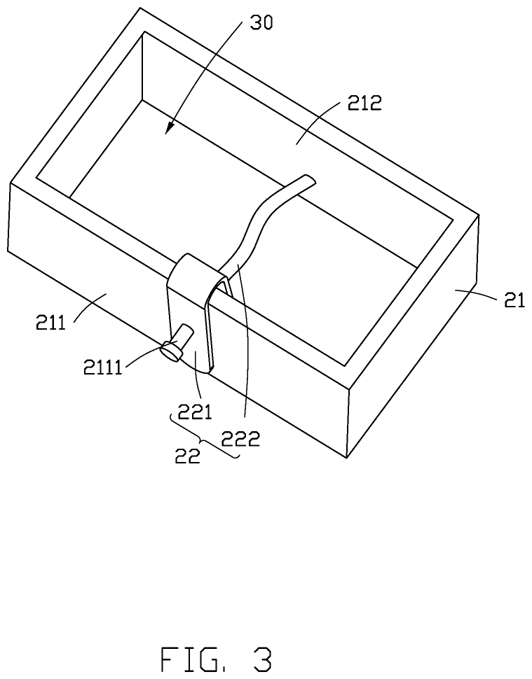

Referring to FIGS. 2 and 3, the cleaning tank 20 includes a tank body 21, a pressing rod 22, and a fixing rod 23. A surface of the tank body 21 is recessed inward to form a groove 30, and the groove 30 is filled with a cleaning solution. The cleaning solution may be one or two of water and ethanol. In one embodiment, the cleaning solution is ethanol. In other embodiments, the cleaning solution may be any other liquid capable of removing contaminants on a surface of the metal wire 102. A material of the tank body 21 may be metal. Specifically, the metal may be copper, iron, or the like. In one embodiment, the tank body 21 includes a first side 211 and a second side 212 opposite to the first side 211.

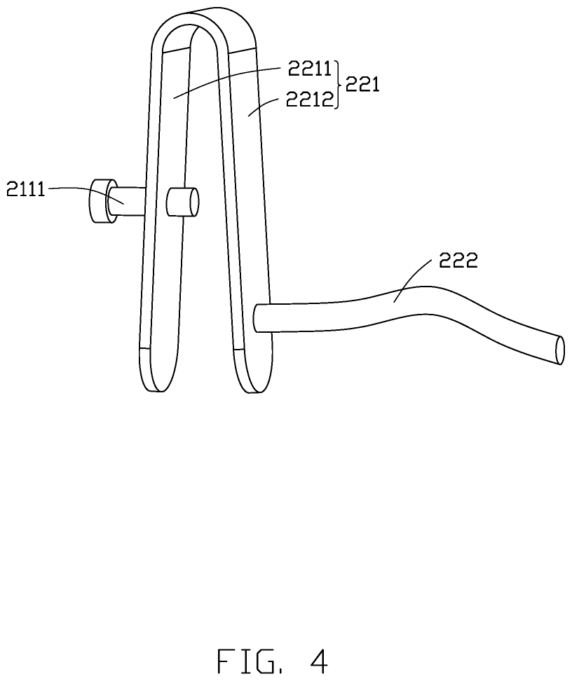

Referring to FIGS. 2-4, the pressing rod 22 is engaged between the first side 211 and the second side 212. In one embodiment, the pressing rod 22 includes a clip 221 and a rod body 222, and the clip 221 is fixed to one end of the rod body 222. The clip 221 is engaged with the first side 211 of the tank body 21, the rod body 222 is located in the groove 30, and another end of the rod body 222 is fixed to the second side 212 of the tank body 21. The pressing rod 22 is in contact with the cleaning solution. In one embodiment, the pressing rod 22 is located below the liquid surface of the cleaning solution. In other embodiments, the pressing rod 22 may be flush with the liquid surface of the cleaning solution. In one embodiment, the clip 221 is substantially U-shaped and includes a first buckle arm 2211 and a second buckle arm 2212 which are oppositely disposed. The first buckle arm 2211 is located outside the groove 30, and the second buckle arm 2212 is located inside the groove 30. A screw 2111 is connected to the first buckle arm 2211, and the screw 2111 passes through the first buckle arm 2211 and through the first side 211, so that the clip 221 is fixed on the first side 211. Correspondingly, the first side 211 has a screw hole (not shown), and the screw hole cooperates with the screw 2111 for the screw 2111 to pass through. As such, during operation, the metal wire 102 passes under the rod body 222, so that the metal wire 102 is completely immersed in the cleaning solution to remove contaminants on the surface of the metal wire 102. In another embodiment, the clip 221 may be engaged with the second side 212 of the tank body 21, so that the rod body 222 is located in the groove 30, and another end of the rod body 222 is fixed to the first side 211 of the tank body 21.

In one embodiment, one end of the fixing rod 23 is connected to the tank body 21, and another end of the fixing rod 23 is connected to the drying element 40 so that the cleaning tank 20 is connected to the drying element 40.

In one embodiment, a dryer (not shown) is provided in the drying element 40, and the dryer quickly blows the cleaning solution off the surface of the metal wire 102.

The tensioner 50 is configured to make the metal wire 102 have a proper tension, so that the metal wire 102 can pass through the wire clamp 60 and the nozzle 70 smoothly. In one embodiment, the tensioner 50 is an air tensioner.

The wire clamp 60 is configured to control a speed at which the metal wire 102 exits.

A heater (not shown) is provided in the nozzle 70, and the heater heats the metal wire 102 passing through the nozzle 70 to melt the metal wire 102. During operation, the metal wire 102 on the rotating body 101 passes through the cleaning tank 20, the drying element 40, the tensioner 50, and the wire clamp 60 in sequence, and is ejected from the nozzle 70, thereby soldering the product to be processed. In one embodiment, the nozzle 70 is a steel nozzle.

The wire bonding machine 100 provided by the present disclosure includes the cleaning tank 20 to remove pollutants from the surface of the metal wire 102, thereby preventing accumulation of pollutants, preventing breakage of the metal wire 102, and improving a working efficiency of the wire bonding machine 100.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A self-cleaning wire bonding machine comprising:
a spool comprising a metal wire;
a nozzle, wherein the metal wire is configured to pass through the nozzle; and
a cleaning tank; wherein:
the metal wire passes through the cleaning tank; and
the metal wire exits out of the nozzle after being heated by the nozzle.

2. The self-cleaning wire bonding machine of claim 1, wherein:
the cleaning tank comprises a tank body and a pressing rod;
a surface of the tank body is recessed inward to form a groove for filling in a cleaning solution;
the tank body comprises a first side and a second side opposite to the first side;
the pressing rod is located between the first side and the second side and located inside the groove; and
the pressing rod contacts the cleaning solution.

3. The self-cleaning wire bonding machine of claim 2, wherein:
the pressing rod comprises a clip and a rod body;
the clip is fixed to one end of the rod body;
the clip is engaged with either the first side or the second side;
the rod body is located within the groove; and
the metal wire passes under the rod body and completely immersed in the cleaning solution.

4. The self-cleaning wire bonding machine of claim 3, wherein:
the pressing rod is located below a liquid surface of the cleaning solution or is flush with the liquid surface of the cleaning solution.

5. The self-cleaning wire bonding machine of claim 3, wherein:
the clip comprises a first buckle arm and a second buckle arm, which are oppositely disposed;
the first buckle arm is located outside the groove, and the second buckle arm is located inside the groove;
a screw passes through the first buckle arm and through the first side or the second side, so that the clip is fixed on the first side or the second side.

6. The self-cleaning wire bonding machine of claim 3, wherein:
the clip is U-shaped.

7. The self-cleaning wire bonding machine of claim 2, further comprising a drying element located on a side of the cleaning tank, wherein the drying element is configured to dry the metal wire after passing through the cleaning tank.

8. The self-cleaning wire bonding machine of claim 7, wherein:
the cleaning tank comprises a fixing rod; and
one end of the fixing rod is coupled to the tank body, and another end of the fixing rod is coupled to the drying element.

9. The self-cleaning wire bonding machine of claim 7, further comprising a tensioner located on a side of the drying element, wherein the tensioner is configured to adjust a tension of the metal wire.

10. A self-cleaning wire bonding machine comprising:
a spool comprising a rotating body and a metal wire wound around the rotating body;
a cleaning tank configured to clean the metal wire after the rotating body passes the metal wire through the cleaning tank;
a drying element configured to dry the metal wire after passing through the cleaning tank;
a tensioner configured to adjust a tension of the metal wire; and
a nozzle configured to heat the metal wire, and the metal wire passes through the nozzle after being heated.

11. The self-cleaning wire bonding machine of claim 10, wherein:
the cleaning tank comprises a tank body and a pressing rod;
a surface of the tank body is recessed inward to form a groove for filling in a cleaning solution;
the tank body comprises a first side and a second side opposite to the first side;
the pressing rod is located between the first side and the second side and located inside the groove; and
the pressing rod contacts the cleaning solution.

12. The self-cleaning wire bonding machine of claim 11, wherein:
the pressing rod comprises a clip and rod body;
the clip is fixed to one end of the rod body;
the clip is engaged with either the first side or the second side;
the rod body is located within the groove; and
the metal wire passes under the rod body and completely immersed in the cleaning solution.

13. The self-cleaning wire bonding machine of claim 12, wherein:
the pressing rod is located below the liquid surface of the cleaning solution or is flush with the liquid surface of the cleaning solution.

14. The self-cleaning wire bonding machine of claim 12, wherein:
the clip comprises a first buckle arm and a second buckle arm which are oppositely disposed;
the first buckle arm is located outside the groove, and the second buckle arm is located inside the groove;
a screw passes through the first buckle arm and through the first side or the second side, so that the clip is fixed on the first side or the second side.

15. The self-cleaning wire bonding machine of claim 13, wherein:
the clip is U-shaped.

16. The self-cleaning wire bonding machine of claim 13, wherein:
the cleaning tank comprises a fixing rod; and
one end of the fixing rod is coupled to the tank body, and another end of the fixing rod is coupled to the drying element.
